(19) United States
(12) Patent Application Publication
(10) Pub. No.: US 2010/0225421 A1
(43) Pub. Date: Sep. 9, 2010

(54) Surface Acoustic Wave Diverter

(75) Inventor: Clinton S. Hartmann, Dallas, TX (US)

Correspondence Address: DEMONT & BREYER, LLC, 100 COMMONS WAY, Ste. 250, HOLMDEL, NJ, 07733, US

(73) Assignee: RF SAW, INC., Richardson, TX (US)

(21) Appl. No.: 12/718,967

(22) Filed: Mar. 6, 2010

Related U.S. Application Data
(60) Provisional application No. 61/209,393, filed on Mar. 6, 2009.
(60) Provisional application No. 61/209,438, filed on Mar. 6, 2009.
(60) Provisional application No. 61/311,309, filed on Mar. 6, 2010.

(51) Int. Cl. H03H 9/25

(52) U.S. Cl. 333/195

(57) ABSTRACT

The present invention is directed to using the uniquely high reflectivity that occurs at high angles of incidence at a boundary between two SAW propagation regions for which the incident wave region has a lower SAW phase velocity. In optical systems, this region is known as the region of total internal reflection. Use of total internal reflection for SAW devices is not well known because it usually only occurs over a narrow range of angles and which are high incidence angles.

### CROSS REFERENCE TO RELATED APPLICATIONS

This application claims the benefit of, and incorporates by reference, U.S. Patent Application Ser. No. 61/209,393, filed 6 Mar. 2009.

This application claims the benefit of, and incorporates by reference, U.S. Patent Application Ser. No. 61/209,438, filed 6 Mar. 2009.

This application claims the benefit of, and incorporates by reference, U.S. Patent Application Ser. No. 61/311,309, filed 6 Mar. 2010.

### FIELD OF THE INVENTION

The present invention relates to surface acoustic wave (SAW) devices and, in particular, to the use of patterned structures on the SAW device substrate surface to divert the direction of SAW energy propagation and is based on the high reflectivity that occurs at high angles of incidence at a boundary between two SAW propagation regions for which the incident wave region has a lower SAW phase velocity. An important application of such diverters is to suppress various types of spurious signals that often distorted SAW device performance. This invention is a lower cost replacement for various acoustic absorber methods commonly used in SAW devices.

### BACKGROUND OF THE INVENTION

Surface acoustic wave (SAW) devices that utilize a planar substrate for propagating surface acoustic waves to implement a wide variety of electronic device functions are well known. In many cases, the planar substrate is a piezoelectric material that facilitates both the generation and reception of SAWs by means of interdigital transducers, or IDTs, that are formed as arrays of interleaved metallic thin film electrodes deposited on the surface of the piezoelectric substrate. In many SAW devices, one IDT launches the SAW in response to an input electronic signal and a second IDT converts the SAW back into an output electronic signal, while in other SAW devices a single IDT performs both the input and output conversion functions.

In most SAW devices, patterned thin films deposited on the surface of the substrate are also used to provide functionality in addition to the IDT. Examples of such functionality include electrical interconnections, grating reflectors, grating filters, multi-strip couplers and waveguides. In many cases this additional functionality and the IDTs can be implemented as part of a single thin metallic film deposition/patterning process while in other cases, the thin film required for a needed element of functionality may be deposited/patterned in a separate process step from forming the IDTs.

The field of SAW device technology initially dealt with Rayleigh-type acoustic surface waves. Over time, the field of SAW device technology has expanded to include a variety of acoustic wave types, including SH type acoustic waves, layered media waves, plate acoustic modes and others. The invention below is generally applicable to all generalized types of SAW devices.

Various methods for diverting the propagation direction of SAWs are known and used in standard SAW devices. Devices with practical importance include grating arrays that are commonly used for both collinear reflection and angled reflection of SAWs. Also, on the multi-strip coupler is a method for diverting SAW energy in multiple ways but it is generally only practical when using Rayleigh type SAWs on strongly piezoelectric materials. Both of these existing methods for diverting SAW propagation generally require significant amounts of substrate area.

Generally all types of SAW devices may generate undesired spurious surface waves that can degrade the SAW device performance. A common class of such spurious surface waves arises from undesired reflections of SAW that may occur at any surface discontinuity that may exist in the path traveled by the SAW on the substrate surface. Typical examples are the undesired reflected spurious SAWs that arise at the edges of the SAW device substrate, and reflections at boundaries of IDTs where interleaved metallic electrodes end and the SAW transitions to propagation of an unmetallized surface.

The common practice in SAW technology is to apply some sort of acoustic absorber material to dampen these undesired acoustic signals . . . . Also, acoustic absorber material is often placed at critical locations of multi-strip coupler structures to suppress other types of undesired spurious signals. Commonly used acoustic absorber materials include black wax, RTV (room-temperature vulcanizing silicon rubber), epoxy resin, polyimide films and other compliance elastic films.

Hypothetically, existing SAW energy diversion methods could be used in place of such absorbers for the purpose of suppressing spurious responses. However, this has not proven to be a practical in the majority of SAW devices due to a variety of reasons that include cost, effectiveness of suppression, and a variety of manufacturing issues. Therefore, acoustic absorbent materials for suppressing spurious SAW signals continue as common practice.

An example of the use of an acoustic absorbent material for suppressing spurious surface waves is disclosed in U.S. Pat. No. 4,354,129 titled “Absorber For Piezoelectric Surface Acoustic Wave Device”, issued to Ieki on Oct. 12, 1982. Ieki teaches use of epoxy resin acoustic absorbers formed on the substrate with a shape that is related to the energy distribution of the acoustic waves. The epoxy absorbers disclosed by Ieki are deposited on the SAW device substrate by conventional techniques such as screen printing. Screen printing of the absorber material represented a significant advance in manufacturing automation compared to manual application of absorber material that had been the previous common practice in SAW technology.

A second example of the use of acoustic absorbent material for suppressing spurious surface waves is disclosed in U.S. Pat. No. 4,931,752 titled “Polyimide Damper for Surface Acoustic Wave Device”, issued to Bray, et al on Jun. 5, 1990. Bray's patent overcomes the disadvantage of epoxies and resins including incompatibility with high temperature sealing due to material flow and/or outgassing, and the difficulties in accurate patterning of the film when using screen printing processes. Bray's patent uses polyimide films that are a highly developed technology for the semiconductor industry which can be readily patterned with high accuracy using conventional photolithographic processes.

A recent third example of patterned acoustic absorbent material for suppressing spurious surface waves is disclosed in a publication titled “Application of Photoimageable Epoxy as an Acoustic Absorber for IF Surface Wave Filter”, by R. E. Chang, et al, 2009 IEEE International Ultrasonics Symposium, paper 5G-4, Rome, Italy, Sep. 20-23, 2009. This paper discloses use of photoimagable epoxy which can be accurately patterned using standard lithography and achieves better absorption properties below 350 MHz than polyimide films.

While the above described prior art has succeeded in suppressing spurious signals by means of deposited absorber films, whether manually deposited or otherwise, all of them suffer a common disadvantage that a significant amount of substrate surface area is usually required in order to achieve adequate suppression of the undesired spurious signals. If the amount of absorber area is reduced, the amount of spurious suppression becomes inadequate and the overall performance of the SAW device is degraded.

The need for rather large substrate surface area for achieving acceptable absorber performance has forced the SAW device design to leave large spaces between the multiple SAW chips that can be simultaneously fabricated on a single SAW device wafer. These large spaces between SAW chips has in turn reduced the number of SAW devices that can be simultaneously manufactured on a single wafer thereby increases the cost of the SAW device. In addition, the increased size of the individual SAW chips has lead to the need for larger ceramic packages for housing the SAW device which further increases device cost. Finally, there are strong market forces for shrinking the size of all electronic hardware and the need to maintain a large device package size, simply to accommodate the application of acoustic absorber material, has had a significant impact on the growth in SAW device application markets simply because the large package size is not acceptable in many new electronic system designs that would otherwise use SAW devices. At present, all absorber materials require significant substrate area to achieve the desired spurious suppression.

It would therefore be highly desirable to have an alternative method for suppressing spurious SAW signals that can be implemented in a much smaller substrate area. Further, the desired suppression method would be inexpensive and simple to implement, and would be generally applicable to all types of SAW devices in all common frequency ranges.

### SUMMARY OF THE INVENTION

The present invention is directed to using the uniquely high reflectivity that occurs at high angles of incidence at a boundary between two SAW propagation regions for which the incident wave region has a lower SAW phase velocity. In optical systems, this region is known as the region of total internal reflection. Use of total internal reflection for SAW devices is not well known because it usually only occurs over a narrow range of angles and which are high incidence angles.

To achieve the desired structure, three problems had to be overcome. First, the normal method for using high angles of incidence would require undesirable structures because they have a large extent along the direction of SAW wave propagation. This problem is solved by using a plurality of much shorter structures, each of which only covers a small portion of the SAW device beamwidth. By placing these shorter structures adjacent to one another, a very compact structure is obtained. The second problem with using the high reflectivity that is only available near total internal reflection is that one must begin the operational part of the structure when the SAW is traveling in a slower velocity region. This problem was solved by having an input region to the structure that can make the transition from any other region from which a wave may be emanating. The final problem is that a transition had to be made to a diverted output wave propagation direction. This problem was solved by placing a plurality of refracting transmission structures that compliment each of the plurality highly reflecting boundaries.

The core invention finally requires a three-sided elemental structure which is then repeated in a compact line disposed across the SAW beamwidth. The three sides of the elemental structure include 1) an input refracting boundary, 2) a boundary with the very high reflectivity, and 3) on output refracting boundary.

### BRIEF DESCRIPTION OF THE DRAWINGS

FIG. 1 shows a top plan view of prior art SAW device filter utilizing acoustic absorbers;

FIG. 2 shows a top plan view of prior art SAW device filter utilizing photoimageable epoxy acoustic absorbers;

FIG. 3 shows an SEM photo closeup view of prior art photoimageable epoxy acoustic absorber;

FIG. 4 shows a top plan view of a preferred embodiment of the current invention;

FIG. 5 shows a top plan view of a preferred embodiment of the current invention; and

FIG. 6 shows a top plan view of a preferred embodiment of the current invention.

### DETAILED DESCRIPTION

A typical SAW filter device configuration is shown in FIG. 1, including a SAW substrate 100, an input IDT transducer 102 for generating SAWs in response to an electronic input signal that is applied to metal pads 102, an output IDT transducer 106 for converting SAWs back to an electronic signal that is available at metal pads 108, and acoustic absorber material 110 that is placed between each IDT and the substrate edge. Said absorber material is effective to suppress spurious response signals that would arise from reflections from edges of the SAW substrate 100 if said absorber material were not present. It is evident from this FIG. 1 that the absorber material requires a significant amount of substrate area.

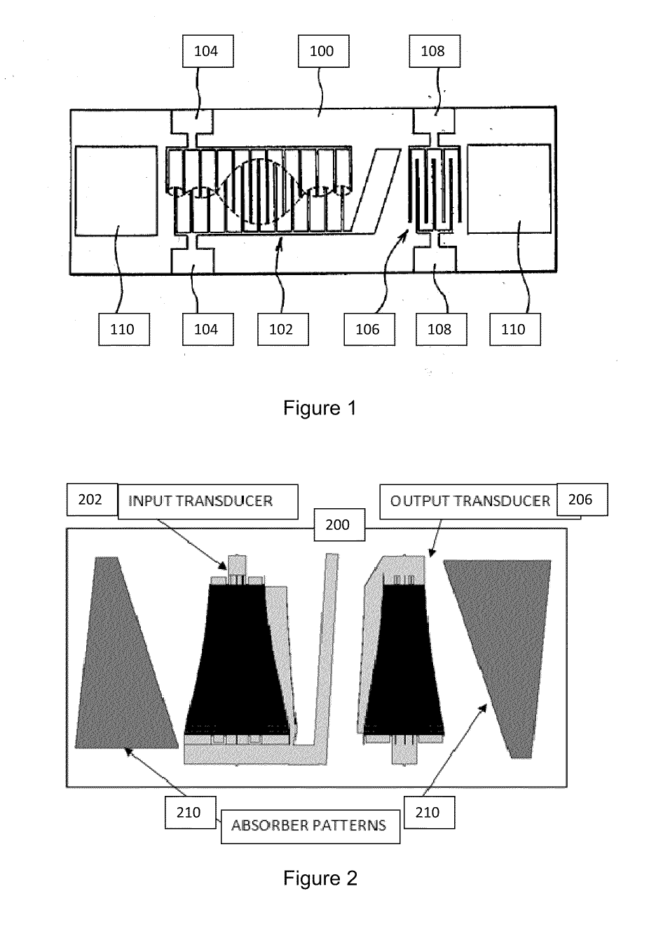

FIG. 2 shows a second typical SAW filter device for which pattern absorber is utilized. The device is comprised of a SAW substrate 200, an input IDT transducer 202, and patterned acoustic absorber 210 as is taught by R. E. Chang, et al, as referenced earlier. It is evident from this FIG. 2 that this particular use of patterned absorber material requires a significant amount of substrate area.

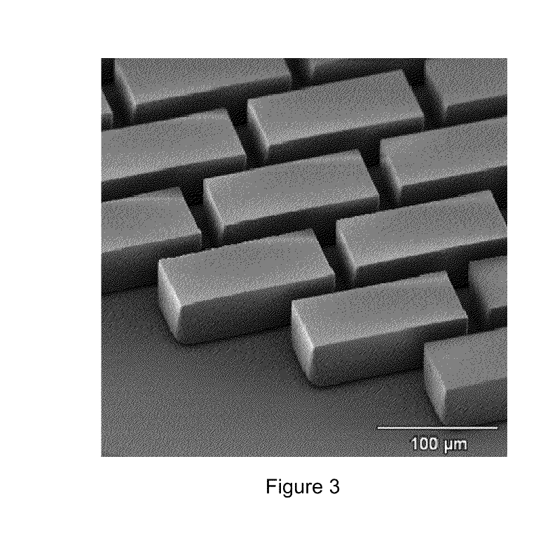

FIG. 3 shows an SEM photo closeup view of prior art photoimageable epoxy acoustic absorber as is taught by R. E. Chang, et al, as referenced earlier. Note the segmentation in the absorber material, which while different than the critical shape of the current invention, clearly illustrates that photoimageable epoxy acoustic absorber could also be used to practice the current invention.

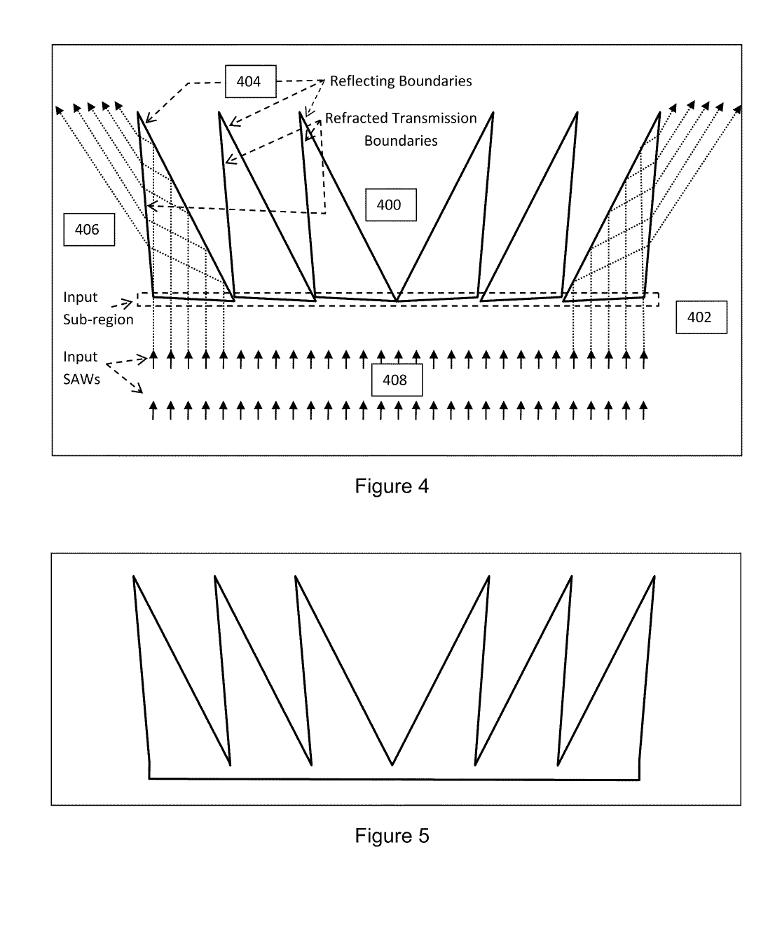

FIG. 4 shows a plan view of a preferred embodiment of the current invention. The overall SAW diverter device, 400, is comprised on a plurality of three sided patterns on the SAW substrate surface. Within the patterned triangular regions, the SAW velocity must be lower than the SAW velocity outside said regions. As shown, the device consists of an input sub-regions, 402, a plurality of reflecting boundaries 404, and a plurality of refracted transmission boundaries 406. The input SAWs are indicated at 408. In operation, different portions of the input SAW enter different ones of the plurality of triangular patterned regions where they encounter the reflecting boundaries 404 at a high angle of incidence. As is well know from geometric optical theory, total internal reflection will occur provided the angle of incidence exceeds the critical angle given by equation 1. The only caveat is that for a geometric optical theory to be valid, the lateral dimensions of the diverting triangular regions must be larger than a small number of acoustic wave lengths. After reflection, the SAWs travel to the refracting transmission boundaries for which the angle of incidence has a smaller value and substantially all of the SAW energy is transmitted outward at a propagation direction that differs significantly from the propagation direction of the input SAWs 408.

$$\text{?} critical \text{?} \text{?} sin ( \frac{v 1}{v 2} ) \\ \text{?} \text{indicates text missing or illegible when filed} \qquad 1 )$$

FIG. 5 shows an alternative preferred embodiment of the current invention in which the input sub-region is continuous as compared to the input sub-region shown in FIG. 4.

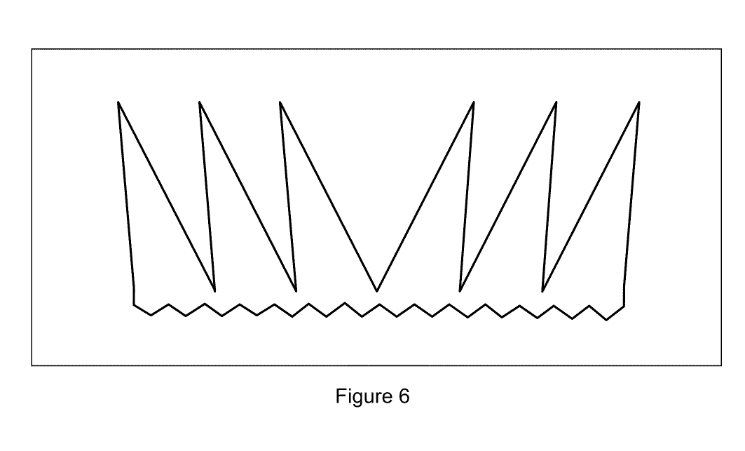

FIG. 6 shows a third preferred embodiment of the current invention in which the input sub-region has a patterned boundary for the purpose of suppressing acoustic reflections at this boundary.

It will be apparent to those skilled in the art that various modifications and variations can be made in the structure and methodology of the present disclosure, without departing from the spririt or scope of the invention. Thus, it is intended tha the present disclosure cover the modifications and variation of the exemplary embodiments described herein, provided that they come within the cope of the appended claims and their equivalents.

What is claimed is:

1. An surface acoustic wave (SAW) diversion structure comprising:
a substrate with a substantially planar surface that is suitable for propagation of SAWs;
a means for generating SAWs that propagate on said planar surface with a known initial SAW propagation direction on said planar surface;
a diverter region on said planar surface with at least two differing SAW velocities disposed in the path of said generated SAWs;
a first input sub-region of said diverter region whereby generated SAWs enter a second sub-region of said diverter region characterized by one of said at least two differing SAW velocities; and
a first structured boundary of said second sub-region generally disposed opposite said first input sub-region, the first structured boundary including a plurality of first reflecting boundaries between regions of differing SAW velocities projecting at a plurality of first angles relative to the initial SAW propagation direction and a plurality of first refracting boundaries between regions of differing SAW velocities projecting at a plurality of second angles relative to the initial SAW propagation direction, each of the first refractive boundaries receiving SAWs from a corresponding one of the first reflective boundaries for a first refractive transmission through said diversion structure with a first SAW transmission propagation direction, wherein said first SAW transmission propagation direction differs from said initial SAW propagation direction.

2. The SAW diversion structure according to claim 1, wherein said substrate contains at least a surface layer of piezoelectric material.

3. The SAW diversion structure according to claim 2, wherein said means for generating SAWs is an interdigital transducer (IDT).

4. The SAW diversion structure according to claim 1, wherein said first reflecting boundaries have a length that exceeds one wavelength of said generated SAW.

5. The SAW diversion structure according to claim 1, wherein the differing SAW velocities on the two sides of the plurality of first reflecting boundaries and said plurality of first angles relative to the initial SAW propagation direction are both arranged to achieve total internal reflection at said reflecting boundaries.

6. The SAW diversion structure according to claim 1, wherein said differing SAW velocities in said diverter region are produced by a pattered thin film.

7. The SAW diversion structure according to claim 6, wherein said pattered thin film is a metallic thin film.

8. The SAW diversion structure according to claim 1, wherein said differing SAW velocities in said diverter region are produced by a pattered material that has acoustic absorber properties.

9. The SAW diversion structure according to claim 1, wherein said first input sub-region has a structured boundary.

10. The SAW diversion structure according to claim 7, wherein said structured boundary of first input sub-region is designed to minimize SAW reflection effects.

11. The SAW diversion structure according to claim 1, wherein diversion structure is disposed on said substrate surface between an IDT structure and an edge of said SAW substrate.

12. The SAW diversion structure according to claim 1, disposed on said substrate surface as a means of providing acoustic wave isolation.

13. An SAW diversion structure with enhanced diversion angle comprising a cascade of two or more SAW diversion structures according to claim 1

14. The SAW diversion structure according to claim 1, further comprising a second structured boundary of said second sub-region generally disposed opposite a second portion of said first input sub-region, the second structured boundary including a plurality of second reflecting boundaries between regions of differing SAW velocities projecting at a plurality of third angles relative to the initial SAW propagation direction and a plurality of second refracting boundaries between regions of differing SAW velocities projecting at a plurality of fourth angles relative to the initial SAW propagation direction, each of the second refractive boundaries receiving SAWs from a corresponding one of the second reflective boundaries for a second refractive transmission through said diversion structure with a second SAW transmission propagation direction, wherein said second SAW transmission propagation direction differs from said initial SAW propagation direction.

15. A SAW device wherein the SAW diversion structure according to claim 14 is disposed on said SAW device substrate surface adjacent to an interdigital transducer (IDT) which contains at least one region with small electrode overlap and further wherein said region of small electrode overlap is placed adjacent to a boundary between said second portion of said first input sub-region a remaining portion of said input sub-region.
